(19) United States
(12) Patent Application Publication
(10) Pub. No.: US 2009/0114264 A1
(43) Pub. Date: May 7, 2009

(54) Fixed-geometry and/or variable-geometry surfaces for capturing solar energy by means of photovoltaic cells, films, and panels, in particular for watercraft

(75) Inventors: GIANROCCO GIAMPIETRO, CONVERSANO (BA) (IT); MICHELE STRAZIOTA, CASAMASSIMA (BA) (IT)

Correspondence Address: YOUNG & THOMPSON, 209 Madison Street, Suite 500, ALEXANDRIA, VA, 22314, US

(73) Assignee: GIANROCCO GIAMPIETRO, CONVERSANO (BA) (IT)

(21) Appl. No.: 12/258,940

(22) Filed: Oct. 27, 2008

(30) Foreign Application Priority Data
Oct. 25, 2007 (IT) BA2007A000068

(51) Int. Cl. H01L 31/042; B63B 17/00

(52) U.S. Cl. 136/244; 114/343

(57) ABSTRACT

A surface for capturing solar energy, which can be applied on a watercraft, characterized in that it is a fixed-geometry and/or variable-geometry surface and includes a plurality of photovoltaic cells and/or films and/or panels for conversion of the solar energy captured into electrical energy. The cells are applied directly or indirectly on the surfaces of a watercraft. In the solution with variable geometry, the surface for capturing solar energy is constituted substantially by a plurality of slats hinged to one another or else by fabrics made so as to enable increase or reduction of the sail surface, but not of the surface for capturing solar energy.

The present invention relates to the sector of alternative energy sources and in particular concerns a technological improvement regarding the use of fixed-geometry and/or variable-geometry surfaces to be fixed on watercraft, with or without sails, said surfaces being equipped with photovoltaic cells for converting the solar energy captured into electrical energy.

Currently known are numerous devices and means for capturing solar energy, which can be applied on watercraft.

In particular, there may be mentioned the German patent DE 3836259 published on Apr. 26, 1990, the German patent DE 19605865 published on Aug. 21, 1997, and the Japanese patent JP 10167186 published on Jun. 23, 1998.

The German patent DE 3836259 published on Apr. 26, 1990, concerns the application on watercraft of solar cells, which are constrained on rigid curvilinear surfaces, which can slide with respect to one another in a telescopic way along a supporting mainmast. Said curvilinear surfaces provided with solar cells are set in such a way as to be lowered or raised, if need be, to supply electrical energy for propulsion and for power supply of the watercraft.

The basic disadvantage of this known art lies in the fact that the solar cells are not applied on the sails and/or on other fixed and/or mobile surfaces of the watercraft.

A further disadvantage is represented by the position of the mainmast, which is central with respect the side masts of the sails, which could shield the light radiation itself either totally or in part.

The patent No. DE 19605865 published on Aug. 21, 1997, regards solar cells that can be applied prevalently on metal fender bars hinged along the sides of watercraft so as to be orientable in relation to the inclination of the sun rays and that supply rechargeable batteries or accumulators for supplying electrical energy for propulsion and power supply of the watercraft.

The basic disadvantage of this invention lies in the fact that the surfaces that capture solar energy appear insufficient for accumulation of an amount electrical energy such as to move the watercraft itself, irrespective of its size, which will require, in any case, other energy contributions.

Furthermore, the surfaces that capture solar energy are not altogether studied for improving the streamlining of the watercraft, but are even prejudicial to the streamlining, and this is an unfavourable factor for sailcraft.

The Japanese patent No. JP 10167186 published on Jun. 23, 1998, concerns a solar-cell module applied to a frame hinged on the end of a mast rigidly constrained to the stern of the sailcraft so as to be orientable in relation to the inclination of the sun rays for supplying rechargeable batteries or accumulators for supplying electrical energy for electric power supply alone of some equipment or systems of the watercraft.

The basic disadvantage of this invention lies in the fact that the surfaces that capture the solar radiation, in addition to being limited in extension, are installed merely as an additional kit. A further disadvantage, not less important than the previous one, is represented by the fact that said surfaces, in addition to being far from extensive, are not aerodynamic at all.

The main purpose of the present invention is to overcome the aforesaid disadvantages of the known art, by providing one or more fixed-geometry and/or variable-geometry surfaces for capture of solar energy and for photovoltaic conversion thereof, which can be applied on watercraft with or without sails for propulsion and electric power supply of the watercraft, combining, at the same time optimizing them, certain characteristics of the previous patents and of the known products referred to above, but overcoming in any case the disadvantages presented thereby.

A further purpose of the present invention is to provide one or more fixed-geometry and/or variable-geometry surfaces for capturing solar energy which can be applied either as an additional kit on electrically propelled watercraft or intimately connected to all the useful surfaces that can be employed, whether fixed surfaces, mobile surfaces or hide-away surfaces, as likewise to all of the external surfaces, whether aerodynamic or not, of the watercraft itself, such as, for example, the sails.

A further purpose of the present invention is to provide one or more surfaces with variable geometry for capturing solar energy that can be applied on electrically propelled watercraft and that will guarantee fully the simplicity and ease of production and that, at the same time, will be easy to use, maintain, and present a high durability and a low cost for the end user.

The above purposes are achieved by providing a complex of surfaces for capturing solar energy, which can be applied on watercraft with or without sails, characterized in that they are fixed-geometry and/or variable-geometry surfaces, said complex being basically constituted by a plurality of photovoltaic cells and/or films and/or panels, which are designed to capture solar energy and which can be applied on all the surfaces of the watercraft, whether fixed surfaces, mobile surfaces, or hide-away surfaces.

The aforesaid purposes and the consequent advantages, as well as the characteristics of the invention will emerge more clearly from the ensuing detailed description of some preferred embodiments, which are provided by way of non-limiting example, with reference to the drawings, wherein:

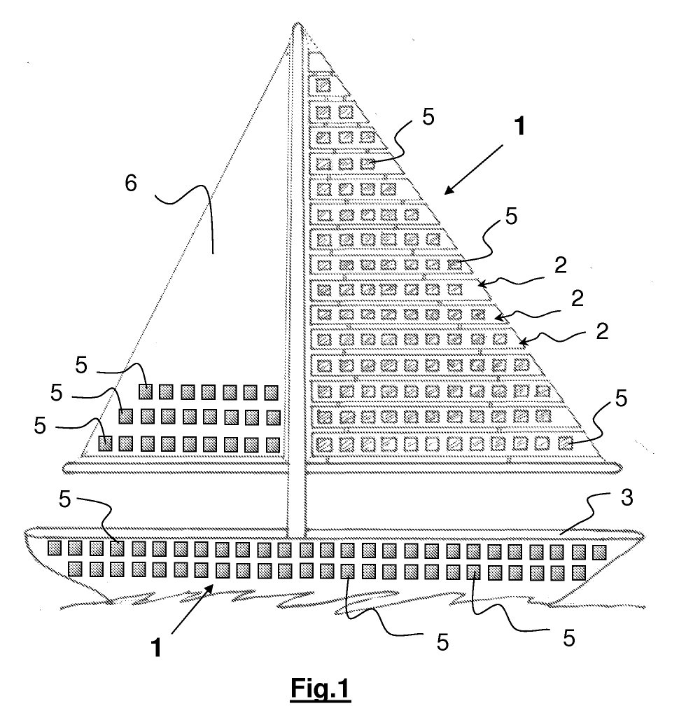

FIG. 1 is a schematic view of a watercraft 3 equipped with a first preferred embodiment of said complex of variable-geometry surfaces 1 for capture of solar energy and photovoltaic conversion thereof, constituted by a plurality of slats 2, connected to one another via a plurality of hinges 4, there being rigidly constrained on said slats a plurality of photovoltaic cells 5 for capturing solar energy;

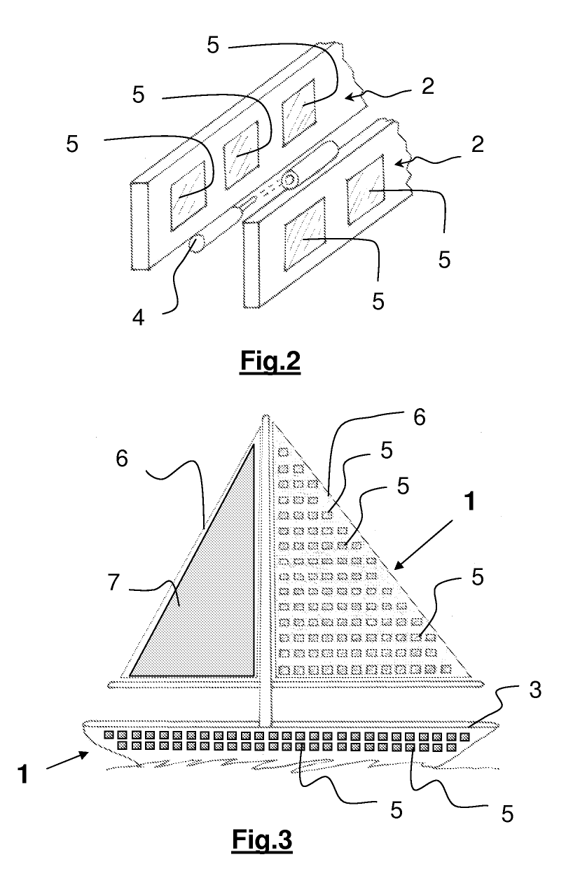

FIG. 2 is a schematic view of the particular preferred solution adopted for connection via a hinge 4 of said slats 2 provided with photovoltaic cells 5 so as to provide a complex of variable-geometry surfaces 1 for capturing solar energy, which can be lowered in the event of strong wind or storm in stack-like fashion, in bellows fashion, in furled fashion, or in a way similar to furling of a sail;

FIG. 3 is a further schematic view of a watercraft 3 with sails 6 provided not only with the first embodiment but also with a second embodiment of said complex of variable-geometry surfaces 1 for capture of solar energy and photovoltaic conversion thereof, constituted by said photovoltaic cells 5 that capture solar energy, which are directly applied on said surface of the sails;

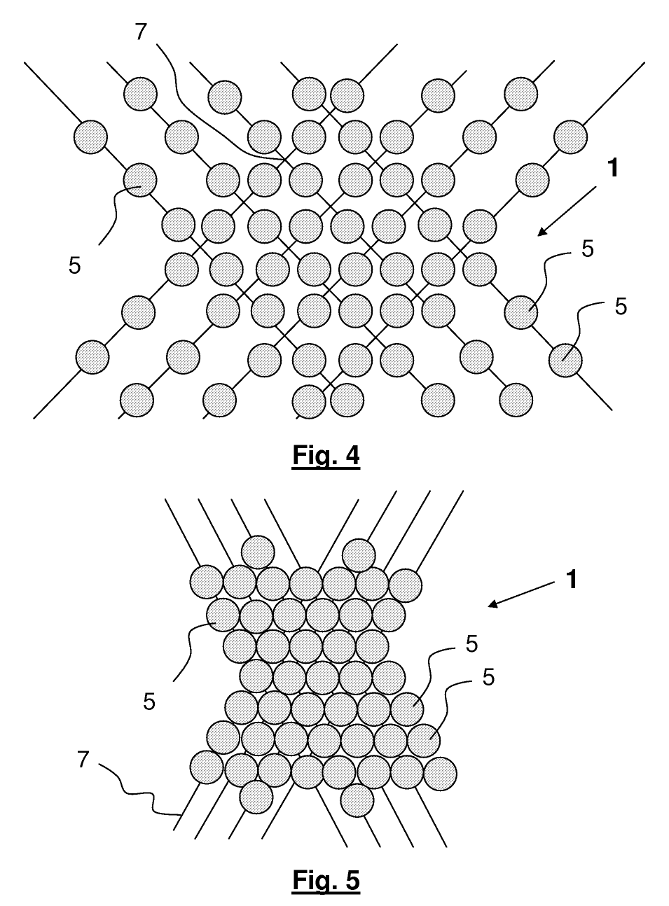

FIG. 4 is a schematic representation of a watercraft 3 provided not only with a second embodiment but also with a third embodiment of said complex of variable-geometry surfaces 1 for capture of solar energy and photovoltaic conversion thereof, constituted by said photovoltaic cells 5 that capture solar energy directly applied on ropes of warp and weft so that with their mutual sliding determine the increase or reduction of the sail surface, but not of the surface for capturing solar energy; and

FIG. 5 is the same schematic representation as that of FIG. 4, from which it emerges how it is possible to obtain a reduction of the sail surface, maintaining the surface for capturing solar energy unvaried.

The complex of fixed-geometry and/or variable-geometry surfaces 1 for capturing solar energy is characterized in that it can be applied on all the surfaces of a watercraft 3, whether they are fixed, mobile and/or hide-away surfaces, by means of photovoltaic cells and/or films and/or panels 5.

The further characterization of the invention is that the complex of surfaces 1 that capture solar energy can be provided also as an integrative part of the outer surface of the fairing of the watercraft 3, and likewise may be present on purposely designed surfaces constituted by elastic or rigid fabrics, provided with a plurality of photovoltaic cells 5 or coated with photovoltaic films 5 or again with photovoltaic panels 5 already pre-sized according to given surface dimensions or provided as additional kits.

Another peculiarity of the present invention is constituted by the presence of a complex of surfaces 1 provided with photovoltaic cells and/or films and/or panels 5 that capture solar energy, which can be made either with variable-geometry surfaces or with fixed-geometry surfaces, even using surfaces that can be hidden away in the fairing of the watercraft 3 itself.

From FIG. 1 it emerges how the complex of surfaces 1 provided with photovoltaic cells and/or films and/or panels 5 that capture solar energy includes fixed-geometry surfaces, like the fairing of the watercraft 3, as well as variable-geometry surfaces, like the sail 6, which is schematically represented, for reasons of simplicity, as being coated only in part with photovoltaic cells 5, and how a first preferred solution of a complex of surfaces 1 is constituted by a plurality of slats 2, which are hinged to one another and coated with photovoltaic cells 5.

Shown in FIG. 2 is an enlarged detail regarding a plurality of hinges of the “photovoltaic” slats 2 for enabling lowering, in a way similar to a sail, of said complex of surfaces 1 in the event of a squall.

Shown in FIG. 3 is a further preferred but non-limiting embodiment of the patent idea, where recourse has been had to the possibility of using fabrics 7 coated with last-generation photovoltaic films or cells. The fabrics 7 can be obtained according to known shuttle techniques, i.e., with warp and weft threads, or in the form of a mesh, i.e., with just warp threads, or with elastic knitted fabric, i.e., with a prevalence of elasticized weft threads, or with non-woven fabrics, or even with technologies that are a combination of the two previous ones, subsequently coated with photovoltaic films.

Further hide-away surfaces, not represented for reasons of brevity in the attached figures, may be installed within the structure of the fairing of the watercraft 3 itself. Said hide-away surfaces extend safely and in a geometrically variable way the overall dimensions of the watercraft 3, guaranteeing, where need be, maximization of the photovoltaic surface for capturing solar energy and hence of supply of electrical energy to the watercraft itself, both when this is sailing and when it is at anchor.

Moving of the mobile variable-geometry surfaces can be obtained either manually or by means of electrical transducers that actuate slide or telescopic mechanisms, or yet again by application of elements hinged so that they can turn through 90° or 180° on the front, side, and/or rear surfaces of the fairing of the watercraft 3, moved with the aid of electrically operated hydraulic jacks, spring mechanisms, automatically and/or manually operated rope mechanisms, etc.

Shown in FIGS. 4 and 5 is a preferred solution of the mode of production of a mesh or shuttle fabric 7 coated with photovoltaic cells, which, by enabling mutual sliding of its weave threads enables the possibility of obtaining a complex of surfaces with variable geometry for capturing solar energy, where it is possible to reduce or increase the contribution of thrust of the wind or instead to increase or reduce the contribution of solar energy.

It is obvious that it is possible to envisage further variants with the possible application of photovoltaic cells on fixed, mobile, and hide-away surfaces of the watercraft 3, via panels with variable geometry which project, according to pre-set curvatures, from both sides of the fairing of the watercraft 3 itself.

The chief advantage of such a location of said plurality of cells, films, and/or panels 5 on the complex of surfaces 1 is that of achieving a maximization of the surface of capture and photovoltaic conversion of solar energy (increasing at least up to three times the capturing surfaces of the inventions according to the prior art), and hence the possibility of capturing energy in an optimal way during navigation, via said variable-geometry surfaces.

The inventive step of the present invention lies fundamentally in having devised a complex of fixed-geometry and/or variable-geometry surfaces 1 for capture and photovoltaic conversion of solar energy via photovoltaic cells, films, and panels, thus enabling the following advantages to be obtained:
possibility of coating all the surfaces of the watercraft;
absence of possible safety problems or risks of detachment or failure of the surfaces of the photovoltaic films and/or panels and/or cells for capturing solar energy, even under the action of wind and rain, given that they are integrally adherent and rigidly constrained to the structure of the watercraft 3 itself;
possibility of charging the accumulators of the watercraft 3 both when this is in port and when it is sailing;
adherence of the cells and/or films and/or panels 5 to the complex of surfaces 1, which further enables improvement of the styling of the watercraft 3 itself.

It should be noted that, according to the invention, even the side walls of the hull can be coated with photovoltaic cells and/or films and/or panels 5: in fact, since said side walls are inclined towards the surface of the sea, they enable the sunlight reflected by the water to be captured.

Finally, it should be noted that, in a further embodiment of the invention, it is possible to envisage application of photovoltaic cells and/or films and/or panels 5 directly on a sail of a known type.

The present invention has been described and illustrated according to some preferred embodiments, but it is understood that a person skilled in the branch may make equivalent modifications and/or replacements, without thereby departing from the sphere of protection of the present industrial patent right.

1. A surface (1) for capturing solar energy, which can be applied on a watercraft (3), characterized in that it is a fixed-geometry and/or variable-geometry surface, and in that it is equipped with a plurality of photovoltaic cells and/or films and/or panels (5) for conversion of the solar energy captured into electrical energy.

2. The surface (1) for capturing solar energy according to claim 1, characterized in that it comprises a plurality of slats (2), hinged to one another, each of which is equipped with one or more photovoltaic cells (5); said photovoltaic cells being rigidly constrained to said slats.

3. The surface (1) for capturing solar energy according to claim 2, characterized in that each of said slats (2) is equipped with at least one hinge (4) that enables a slat to be constrained to the adjacent one, to enable variability of the geometry of the surface (1) itself; it being possible to lower or hoist said surface in stack-like fashion, in bellows fashion, in furled fashion, or in a way similar to a sail (6).

4. The surface (1) for capturing solar energy according to claim 1, characterized in that it is constituted by a fabric (7) that is equipped with a plurality of photovoltaic cells (5); said fabric (7) being a shuttle fabric, i.e., with warp and weft threads, or a mesh fabric, i.e., with just warp threads, to enable a surface (1) with variable geometry to be obtained.

5. The surface (1) for capturing solar energy according to claim 1, characterized in that it is constituted by a elasticized knitted fabric (7), which is equipped with a plurality of photovoltaic cells (5), to enable a surface (1) with variable geometry to be obtained.

6. The surface (1) for capturing solar energy according to claim 1, characterized in that it is constituted by a non-woven fabric (7), which is equipped with a plurality of photovoltaic cells (5), to enable a surface (1) with fixed or variable geometry to be obtained.

7. The surface (1) for capturing solar energy according to claim 1, characterized in that it is constituted by a fabric (7) coated with rigid and/or flexible photovoltaic films (5).

8. The surface (1) for capturing solar energy according to claim 1, characterized in that it comprises a plurality of ropes of warp and weft coated with photovoltaic cells (5); mutual sliding of said ropes determining increase or reduction of the sail surface, but not of the surface for capturing solar energy.

9. The surface (1) for capturing solar energy according to claim 1, characterized in that said photovoltaic cells and/or films and/or panels (5) are applied directly on a sail of a known type.

10. A watercraft characterized in that it comprises one or more surfaces (1) according to claim 1.

11. An assembly kit for installation on a watercraft (3) of at least one surface designed for capturing solar energy according to claim 1 characterized in that it comprises, in combination:
a plurality of slats (2) of appropriate length to be hinged to one another; and
at least one photovoltaic cell (5) to be constrained to each slat (2).
